(19) United States
(12) Patent Application Publication
(10) Pub. No.: US 2008/0137700 A1
(43) Pub. Date: Jun. 12, 2008

(54) Semiconductor Laser Device and Method for Manufacturing Same

(75) Inventor: Takeshi Yamamoto, Kyoto (JP)

Correspondence Address: HAMRE, SCHUMANN, MUELLER & LARSON, P.C., P.O. BOX 2902, MINNEAPOLIS, MN, 55402-0902, US

(73) Assignee: Rohm Co., Ltd, Kyoto (JP)

(21) Appl. No.: 11/795,064

(22) PCT Filed: Jan. 5, 2006
(86) PCT No.: PCT/JP2006/000024

§ 371 Date: Jul. 11, 2007

(30) Foreign Application Priority Data
Jan. 11, 2005 (JP) 2005-003694

(51) Int. Cl. H01S 5/022; H01L 21/60

(52) U.S. Cl. 372/43.01; 438/26; 257/E21.509

(57) ABSTRACT

A semiconductor laser device (A) includes a base (1A) a block (1B) fixed to the base, and a semiconductor laser element (2) provided at the block. The semiconductor laser device (A) further includes a lead (4A) extending through the base (1A) and electrically connected to the semiconductor laser element (2). A cap (5) is fixed to the upper surface of the base (1A), to surround the semiconductor laser element (2) and an end of the lead (4A). The cap (5) is formed with an opening (5d) provided in the light emitting direction of a laser beam emitted from the semiconductor laser element (2). Accordingly, the cap (5) is open in the light emitting direction the laser beam.

### TECHNICAL FIELD

The present invention relates to a semiconductor laser device and a manufacturing method of the same. Specifically, the present invention relates to a semiconductor laser device used as a light source for reading data out from CD (Compact Disc), MD (Mini Disc), and DVD (Digital Versatile Disc), or for writing data into CD-R/RW (Compact Disc Recordable/Rewritable) and DVD-R/RW (Digital Versatile Disc Recordable/Rewritable).

### BACKGROUND ART

FIG. 8 illustrates a conventional semiconductor laser device disclosed in JP-A-2004-31900. The semiconductor laser device X emits laser beams upwardly in the figure. Description of the semiconductor laser device X is given below.

The semiconductor laser device X includes a stem 91. The stem 91 includes a base 91A and a block 91B. A semiconductor laser element 92 is provided on the block 91B. A light receiving element 93 is provided above the base 91A. The base 91A is formed with two through-holes 91Aa.

Leads 94A, 94B extend through the through-holes 91Aa. The lead 94A is electrically connected to the semiconductor laser element 92 via a wire, while the lead 94B is electrically connected to the light receiving element 93. Gaps between the through-holes 91Aa and the leads 94A, 94B are filled with low-melting glass 97. A lead 94C is bonded to the lower surface of the base 91A.

The block 91B is covered with a cap 95. The cap 95 is formed with an opening 95a at its top portion. The opening 95a is shielded by a glass panel 96. The glass panel 96 allows the passage of laser beams emitted from the semiconductor laser element 92. The brim of the cap 95 is bonded to the base 91A by resistance welding.

In the conventional arrangement, the space defined by the base 91A and the cap 95 is hermetically sealed off from the outside of the semiconductor laser device A. Thus, even if the semiconductor laser device X is used in an environment with a high humidity, the semiconductor laser element 92 is not exposed to the humid air, but is properly protected.

Recently, the access rate to a recording medium such as CD-R has been increased. Accordingly, a semiconductor laser device having high light intensity is required. Especially when used as a light source for writing into CD-R/RW or DVD-R/RW, high light intensity is required.

When the light intensity of the semiconductor laser device is increased, the semiconductor laser device tends to generate a larger amount of heat. In the semiconductor laser device X, the semiconductor laser element 92 is accommodated in an airtight space defined by the base 91A and the cap 95. Thus, the heat generated from the semiconductor laser element 92 cannot be released appropriately to the outside. This results in an excessive temperature rise at the semiconductor laser element 92, and the semiconductor laser element 92 may fail to perform proper emission of laser beams.

### DISCLOSURE OF THE INVENTION

The present invention is proposed under the above-described circumstances, and thus an object of the present invention is to provide a semiconductor laser device having enhanced heat dissipation and capable of emitting light with high intensity. Another object of the present invention is to provide a manufacturing method for making such a semiconductor laser device.

To achieve the above objects, the present invention employs the following technical features.

A semiconductor laser device according to a first aspect of the present invention comprises a base, a block fixed to the base, a semiconductor laser element provided at the block, a lead provided through the base in electrical connection to the semiconductor laser element, and a cap fixed to the base to surround the semiconductor laser element and an end of the lead. The cap is formed with an opening provided in a light emitting direction of a laser beam emitted by the semiconductor laser element, where the opening causes the cap to be open in the light emitting direction.

With the above structure, the space surrounded by the cap and the base is not hermetically sealed, but configured to communicate with the outside of the semiconductor laser device through the opening. Thus, even if the semiconductor laser element generates heat in use of the semiconductor laser device, the heat can be dissipated outside of the semiconductor laser device through the opening. Accordingly, the semiconductor laser element is prevented from being overheated. Thus, when used as a light source for writing to e.g. CD-R/RW, the light intensity can be properly increased to deal with a higher access rate.

Preferably, the base and the block may be formed integral with each other from a single kind of material. With this arrangement, the heat transmission between the block and the base is enhanced. Accordingly, the heat from the semiconductor laser element is not only dissipated through the opening but also transmitted to the base via the block.

Preferably, the base and the block may be made of either Cu or a Cu alloy. In this manner, the thermal conductivity of the base and the block is advantageously high, whereby the temperature rise at the semiconductor laser element is restrained.

Preferably, the lead may be fixed to the base via a resin portion. With this configuration, the lead and the base are electrically insulated from, but mechanically connected to each other. If glass is used for this connection, a temperature as high as 1000° C. or more is required for the baking. On the other hand, when resin is used, the baking process can be performed at a relatively low temperature of about 200-300° C. Accordingly, even the base and the block are provided with Au plating before the baking process, the Au plating is not damaged during the baking process. According to the present invention, plating of other materials than Au may be performed, and other kinds of surface treatment may be performed.

Preferably, the resin portion may be made of one of a thermosetting resin, a thermoplastic resin and a silicone resin. The thermosetting resin may be epoxy. The thermoplastic resin may be polyphenylene sulfide, polyphthalamide, or liquid crystalline polyester. The silicone resin may be mixed with silica powder. These resin materials are suitable for attaining reliable mechanical connection and electrical insulation, with the baking temperature kept relatively low.

Preferably, the base and the block may be provided with either a stack of Ni/Pd/Au plating or a stack of Ni/Au plating. With this configuration, the base and the block are protected from oxidization.

Preferably, the semiconductor laser element may be moisture-resistant. In this instance, even when the semiconductor laser device is used in a highly humid environment, the emitting surface of the semiconductor laser element does not deteriorate, which ensures proper operation. The moisture-resistant semiconductor laser element may be provided with, at the emitting surface, a coating made of Al₂O₃ mixed with TiO or SiO₂ by sputtering.

According to a second aspect of the present invention, there is provided a manufacturing method of a semiconductor laser device. This method comprises the steps of: forming a stem including a base and a block fixed to the base; fixing a lead in a through-hole formed in the base; and mounting a semiconductor laser element on the block. In the step of forming the stem, the block and the base are formed integral with each other. With such a configuration, the stem has a high thermal conductivity, which prevents the overheating of the semiconductor laser element.

Preferably, the stem may be formed by cold-forging from Cu or a Cu alloy. Such a material is suitable for preventing excessive temperature rise at the semiconductor laser element. Further, since the above materials are easily processible, a desired form can be produced accurately by cold-forging.

Preferably, the lead may be fixed to the through-hole using a resin material. Since the baking temperature of the resin material is relatively low, the stem can be provided with plating which does not have high heat resistance.

Preferably, the resin material may be one of a thermosetting resin, a thermoplastic resin and a silicone resin. The thermosetting resin may be epoxy. The thermoplastic resin may be polyphenylene sulfide, polyphthalamide or liquid crystalline polyester. The silicone resin may be mixed with silica powder. By using such materials, the baking temperature is about 200-300°, for example.

Preferably, the manufacturing method of the present invention may further comprise an additional step for providing the stem with one of Ni/Pd/Au plating and Ni/Au plating, where the additional step is performed after the stem forming step and before the lead fixing step. In this instance, the lead may be provided, in advance, with Au plating having a thickness of 0.1 μm or more for improving the bonding strength of a wire. Meanwhile, the stem may be provided with no Au plating or with Au plating having a thickness of 0.01 μm or less for preventing oxidization. In this way, the relatively expensive Au plating is reduced, thereby cutting the cost.

Preferably, the manufacturing method of the present invention may further comprise an additional step for providing the lead with Au plating before the lead fixing step. With this arrangement, an Au plating layer thick enough to enhance the bonding strength to a wire is formed on the lead only. In other words, there is no need to form an unnecessarily thick Au plating layer on the stem, for example. This is advantageous to a cost reduction.

Other features and advantages of the present invention will be described below with reference to the accompanying drawings.

### BRIEF DESCRIPTION OF THE DRAWINGS

FIG. 1 is a perspective view illustrating a semiconductor laser device according to the present invention.

FIG. 2 is a sectional view taken along lines II-II of FIG. 1.

FIG. 3 is a sectional view taken along lines III-III of FIG. 1.

FIG. 4 is a sectional view illustrating a process of manufacturing method of the semiconductor laser device according to the present invention.

FIG. 5 is a sectional view illustrating another process of the manufacturing method.

FIG. 6 is a sectional view illustrating another process of the manufacturing method.

FIG. 7 is a sectional view illustrating another process of the manufacturing method.

FIG. 8 is a sectional view illustrating a conventional semiconductor laser device.

### BEST MODE FOR CARRYING OUT THE INVENTION

A preferred embodiment of the present invention is described below with reference to the accompanying drawings.

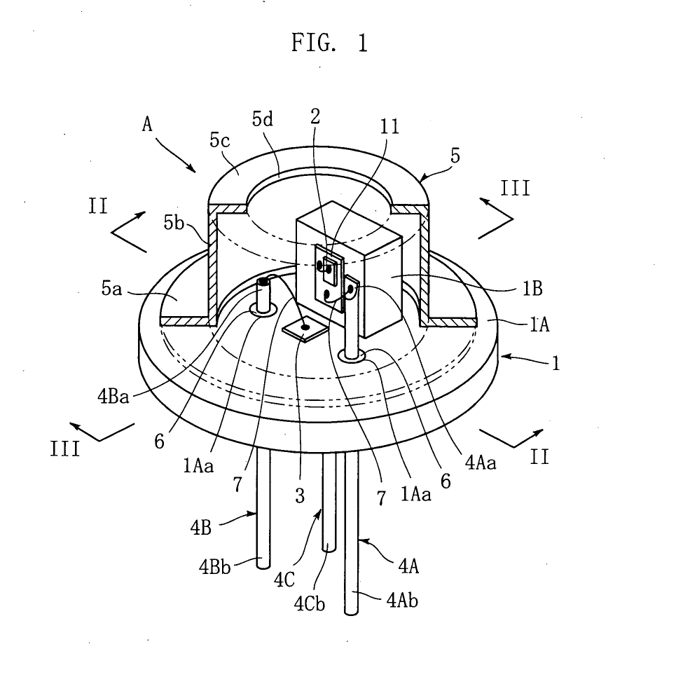

FIGS. 1-3 show a semiconductor laser device according to the present invention. The illustrated semiconductor laser device A is configured to emit laser beams upward as viewed in FIG. 1. The semiconductor laser device A includes a stem 1, a semiconductor laser element 2, a light receiving element 3, leads 4A, 4B, 4C and a cap 5.

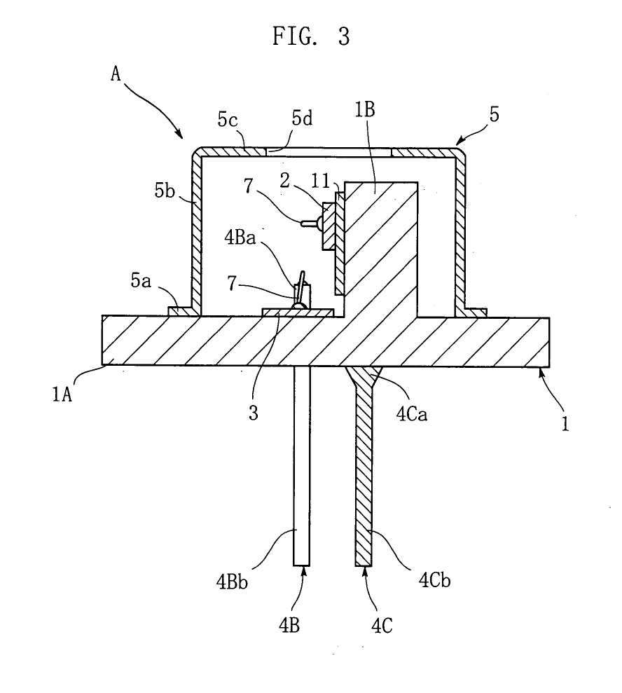

The stem 1 includes a base 1A and a block 1B. As shown in FIG. 3, the base 1A and the block 1B are integrated into a single piece to form the stem 1. The stem 1 (i.e. the base 1A and the block 1B) is made of Cu or a Cu alloy, and has its surface plated with a stack of Ni/Pd/Au or a stack of Ni/Au. The Au plating has a thickness of about 0.01 μm or less. As shown in FIG. 1, the base 1A is a circular plate and the block 1B is a rectangular parallelepiped. The block 1B is set on the upper side of the base 1A at a position offset from the center of the base 1A. The base 1A has a thickness of about 1.2 mm and a diameter of about 5.6 mm, for example.

The semiconductor laser element 2 is mounted on a sub-mount 11 provided on a side surface of the block 1B. The semiconductor laser element 2 emits laser beams. The semiconductor laser element 2 may have a size of 250 μms square up to 250 μm×800 μm, for example. The sub-mount 11 is made up of a silicon board or AIN (aluminum nitride) board, and normally may have a size of 0.8 mm×11.0 mm, for example. The semiconductor laser element 2 is of a moisture-resistant type. Specifically, the semiconductor laser element 2 includes a light emitting surface that is covered with a coating layer formed by sputtering of Al₂O₃ mixed with TiO or with SiO₂, for example. Thus, even when the moisture-resistant semiconductor laser element 2 is put in a highly humid environment, its emitting surface is prevented from deteriorating.

The light receiving element 3 is set on the upper surface of the base 1A. The light receiving element 3 is configured to output a signal corresponding to the intensity of received light. Based on the output from the light receiving element 3, it is possible to maintain the light emission from the semiconductor laser device A at a constant level. To this end, the output from the light receiving element 3 is sent, as a feedback signal, to a circuit for controlling the operation of the semiconductor laser element 2.

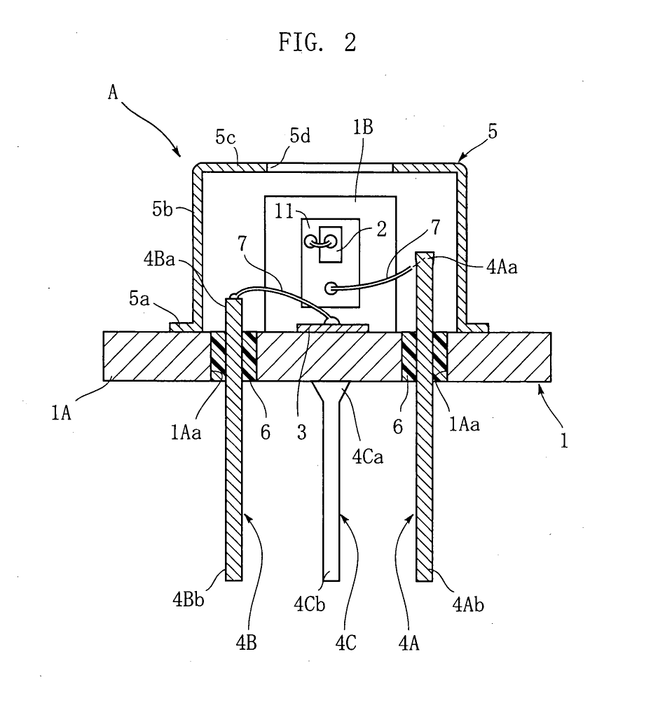

The leads 4A, 4B supply electric power to the semiconductor laser element 2 and the light receiving element 3, respectively. As shown in FIG. 2, the leads 4A, 4B extend through the through-holes 1Aa formed in the base 1A. The leads 4A, 4B are made of e.g. Fe—Ni alloy and plated with Au. The Au plating is for facilitating wire bonding to be described below, and has a thickness of about 0.1 μm or more, for example. The leads 4A, 4B are fixed to the base 1A by resin portions 6. The resin portions 6 are made of a thermosetting resin such as epoxy resin, a thermoplastic resin such as polyphenylene sulfide, polyphthalamide, and liquid crystalline polyester, or a silicone resin mixed with silica powder. With such resin portions 6, the leads 4A, 4B are mechanically connected to the base 1A, and electrically insulated therefrom.

The lead 4C is provided on the lower side of the base 1A. The lead 4C includes an upper end 4Ca which may be brazed to the base 1A. Thus, the lead 4C is electrically connected to the base 1A. The lead 4C is made of Fe—Ni alloy. Differing from the leads 4A, 4B but likewise to the stem 1, the lead 4C is plated with a stack of Ni/Pd/Au or a stack of Ni/Au. The Au plating of the lead 4C has a thickness of about 0.01 μm, for example.

As shown in FIG. 1, the obverse surface of the semiconductor laser element 2 is electrically connected to an upper end 4Aa of the lead 4A by a wire 7 and via the sub-mount 11. The reverse surface of the semiconductor laser element 2 is electrically insulated from the sub-mount 11 but connected to the block 1B. As shown in FIG. 3, the block 1B is electrically connected to the lead 4C via the base 1A. In this manner, the semiconductor laser element 2 is electrically connected to both the lead 4A and the lead 4C. As shown in FIG. 2, the upper surface of the light receiving element 3 is connected to an upper end 4Ba of the lead 4B by another wire 7, while the lower surface of the light receiving element 3 is electrically connected to the lead 4C via the base 1A. The lead 4C serves as a common lead. The leads 4A, 4B, 4C include lower ends serving as terminals 4Ab, 4Bb and 4Cb used for providing electrical and mechanical connection between the semiconductor laser device A and another electronic device.

As shown in FIG. 1, the cap 5, supported on the upper surface of the base 1A, includes a flange 5a, a cylindrical portion 5b, and a top portion 5c. The cap 5 protects the semiconductor laser element 2, the light receiving element 3, and the connecting wires 7 from being damaged by an external force. To this end, the cylindrical portion 5b is longer than the block 1B in the vertical direction. The cap 5 is made of Fe—Ni—Co alloy such as Kovar (registered trademark), for example. The cap 5 is fixed to the base 1A by resistance welding, for example. Alternatively, use may be made of an epoxy adhesive. The top portion 5c is formed with an opening 5d. The laser beams emitted upwardly from the semiconductor laser element 2 passes through the opening 5d to go out of the semiconductor laser device A. The opening 5d is left unclosed, with no transparent glass element nor any other element fitted into it. Thus, as seen from FIGS. 2 and 3, the space around the semiconductor laser element 2 is open to the outside.

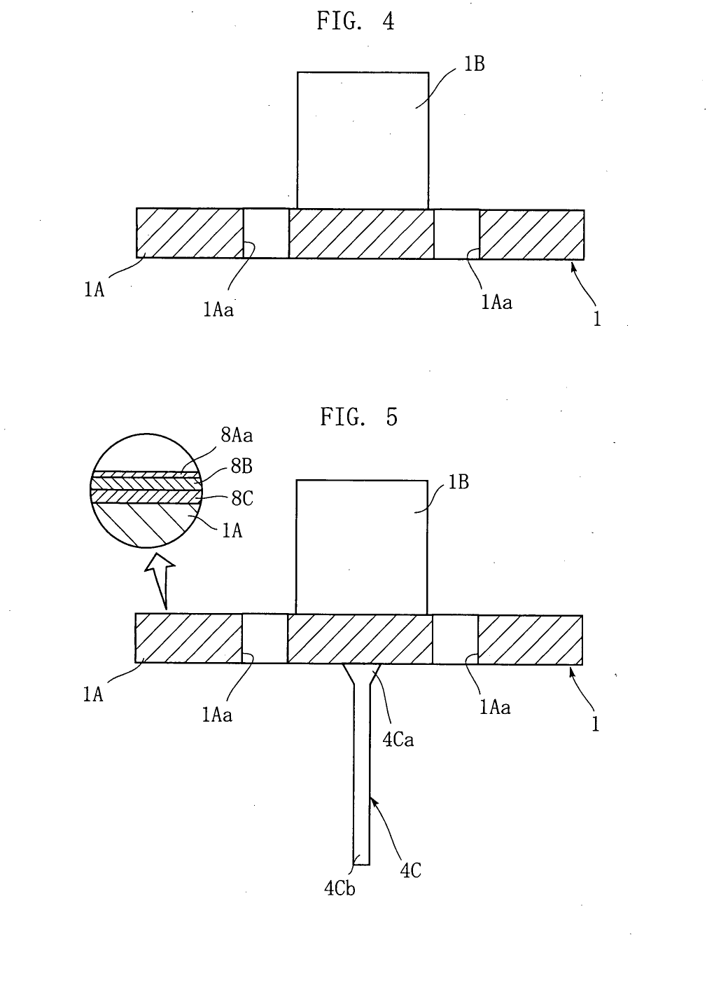

Next, an example of a manufacturing method of the semiconductor laser device A is described below with reference to FIGS. 4-7.

First, as shown in FIG. 4, cold-forging is performed to Cu or Cu alloy material to form the stem 1. By the cold-forging process, the base 1A and the block 1B are integrally formed as shown in FIG. 3. At the same time, the base 1A is formed with two through-holes 1Aa through which the leads 4A, 4B are provided. The stem 1 is preferably made by cold-forging in view of dimensional accuracy and manufacturing efficiency, but not limited to this. Alternatively, use may be made of another manufacturing method that provides the same dimensional accuracy as the cold-forging

Next, as shown in FIG. 5, the lead 4C may be brazed to the lower surface of the base 1A, so that the lead 4C and the base 1A are electrically connected to each other. A method other than brazing may be utilized to electrically connect the lead 4C and the base 1A. After the fixing of the lead 4C, the stem 1 and the lead 4C are subjected to plating. Specifically, Ni plating 8C and Pd plating 8B are first provided, and then Au plating 8Aa is provided thereon. As described above, the Au plating 8Aa has a thickness of about 0.01 μm or less, to prevent the stem 1 and the lead 4C from being oxidized. Depending on the environment in which the semiconductor laser device A is to be used, the above plating process may not include the Pd plating 8B, while the Ni plating 8C and the Au plating 8Aa may remain.

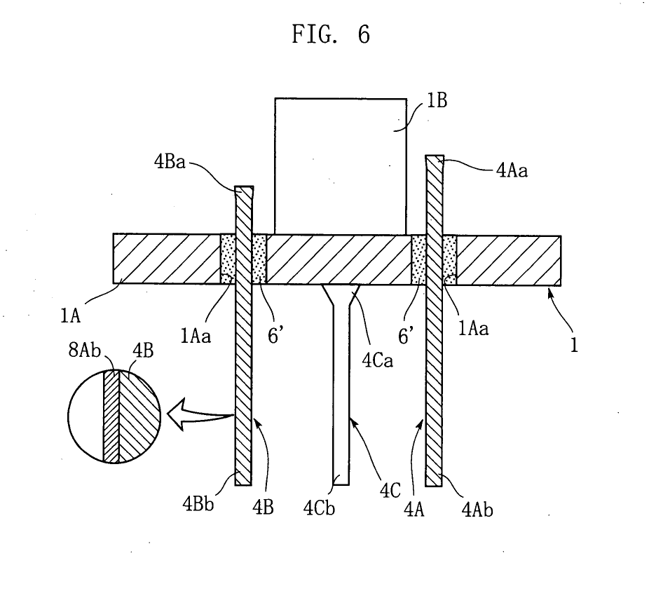

Subsequently, as shown in FIG. 6, the leads 4A and 4B with the Au plating 8Ab are inserted into the through-holes 1Aa. The Au plating 8Ab, which may be at least 0.1 μm in thickness, is provided for facilitating the connection of Au wires to the leads 4A, 4B. Then, the through-holes 1Aa are filled with resin paste 6′ to fix the leads 4A, 4B. The resin paste 6′ may contain a thermosetting resin such as epoxy resin, a thermoplastic resin such as polyphenylene sulfide, polyphthalamide, and liquid crystalline polyester, or a silicone resin mixed with silica powder. The filling of the resin paste 6′ may be performed before or after the inserting of the leads 4A, 4B into the through-holes 1Aa.

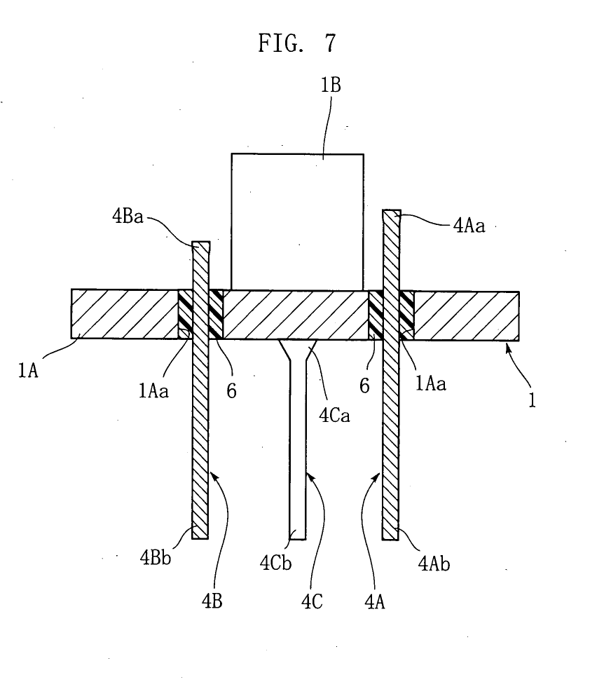

Thereafter, the resin paste 6′ is baked to form the resin portions 6. In this way, as shown in FIG. 7, the leads 4A, 4B are fixed to the base 1A by the resin portions 6. Since the resin paste 6′ contains the above-described material, a baking temperature of about 200-300° C. suffices. The resin paste 6′ is baked together with the stem 1 and the leads 4A, 4B, 4C. The Au plating 8Aa, 8Ab provided on the stem 1 and the leads 4A, 4B, 4C tends to be melted or peeled off under a high temperature of no less than 1000° C. However, since the resin paste 6′ is baked under a relatively low temperature of about 200-300° C., the Au plating 8Aa, 8Ab is not damaged due to high temperature. With the resin portions 6, the leads 4A, 4B are fixed to the base 1A, and electrically insulated therefrom.

Then, the sub-mount 11 as shown in FIG. 1 is formed, the semiconductor laser element 2 and the light receiving element 3 are mounted, the wire bonding is performed, and the cap 5 is fixed, whereby the semiconductor laser device A is completed. For efficient bonding of the cap 5, resistance welding may be suitable. The cap 5 needs not to be bonded through the entire circumference of the flange 5a. The resistance welding may be performed at several portions of the flange 5a to ensure that the cap 5 does not easily come off the base 1A.

The functions of the semiconductor laser device A will be described below.

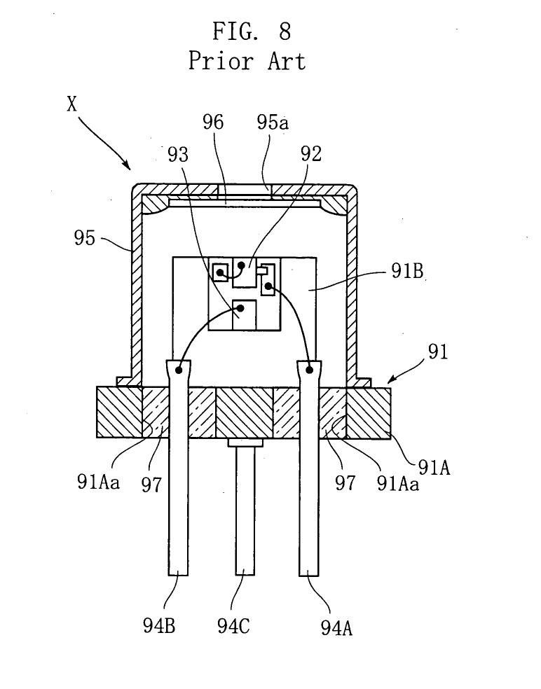

In the conventional device shown in FIG. 8, the semiconductor laser element 92 is provided in the closed space. Thus, the heat generated at the semiconductor laser element 92 is trapped within the cap 95. According to the present embodiment, on the other hand, as shown in FIG. 1, the space surrounded by the cap 5 and the base 1A is not hermetically sealed, but is configured to communicate with the outside of the semiconductor laser device A through the opening 5d. Thus, the generated heat from the semiconductor laser element 2 is dissipated to the outside of the semiconductor laser device A by heat transmission or heat convection through the opening 5d. As a result, the semiconductor laser element 2 is prevented from being excessively heated. When the semiconductor laser device A is used as a light source for writing to e.g. CD-R/RW, the above arrangement contributes to attaining greater output corresponding to a higher access rate.

Further, since the base 1A and the block 1B of the stem 1 are formed integral with each other, the heat transmission is enhanced. Thus, the generated heat from the semiconductor laser element 2 is efficiently transmitted to the base 1A via the block 1B. Accordingly, in addition to the heat dissipation through the opening 5d, heat release from the semiconductor laser element 2 is much enhanced. This is preferable for increasing output of the semiconductor laser device A. It is also advantageous for heat dissipation of the semiconductor laser element 2 that the stem 1 is made of Cu or Cu alloy, which has relatively high thermal conductivity.

The leads 4A, 4B are fixed to the base 1A via the resin portions 6. In this way, the leads 4A, 4B are firmly bonded to the base 1A, and the leads 4A, 4B are electrically insulated properly from the base 1A.

The resin portions 6 according to the present embodiment are made of a material to be baked under relatively low temperature of about 200-300° C. Thus, as shown in FIG. 6, Au plating can be provided to the stem 1 and leads 4A, 4B, 4C before the resin paste 6′ is baked to fix the leads 4A, 4B.

The leads 4A, 4B, which are connected to the semiconductor laser element 2 and the light receiving element 3 via the wires 7, need to be provided with Au plating having a thickness of 0.1 μm or more. On the other hand, the stem 1 and the lead 4C, only to prevent oxidization, need to be provided with Au plating having a thickness of 0.01 μm at most.

In this way, thickness of Au plating necessary for each of the components can be reasonably selected, so that the amount of relatively expensive Au plating is controlled, and thus the product cost is reduced.

The semiconductor laser device according to the present invention is not limited to the above-described embodiment. The structures of the components of the semiconductor laser device may be variously modified.

The stem 1 is preferably made of Cu or Cu alloy, though the present invention is not limited to this. The stem 1 may be made of a material such as Fe that is capable of reliably preventing temperature increase at the semiconductor laser element 2. Further, preferably the base 1A and the block 1B of the stem 1 are formed integral with each other. However, as long as the temperature increase of the semiconductor laser element 2 is prevented, a non-integral structure may be employed.

It suffices for the cap 5 to have an opening 5d to provide an open configuration in the light emitting direction of the semiconductor laser element 2. The cap may include only the flange 5a and the cylindrical portion 5b, so that the dimension of the opening is the same as the outer diameter of the top portion 5c.

It is advantageous to include the light receiving element 3 for stable light emitting of the semiconductor laser element 2 which is controlled by feedback, for example. However, the present invention is not limited to this, and the light receiving element 3 may be omitted by performing output control of the semiconductor laser element 2 utilizing other method.

The semiconductor laser device A is suitable for light source for reading out from CD, MD, and DVD, or for writing into CD-R/RW and DVD-R/RW. However, the present semiconductor laser device is not limited to this, and may be widely used as a light source for emitting laser beams in an electronic apparatus.

1. A semiconductor laser device comprising:
a base;
a block fixed to the base;
a semiconductor laser element provided at the block;
a lead extending through the base and electrically connected to the semiconductor laser element; and
a cap fixed to the base, the cap surrounding the semiconductor laser element and an end of the lead;
wherein the cap is formed with an opening provided in a light emitting direction of a laser beam emitted from the semiconductor laser element, the cap being open in the light emitting direction.

2. The semiconductor laser device according to claim 1, wherein the base and the block are formed as a single piece made of a same material.

3. The semiconductor laser device according to claim 2, wherein the material is one of Cu and a Cu alloy.

4. The semiconductor laser device according to claim 1, wherein the lead is fixed to the base via a resin portion.

5. The semiconductor laser device according to claim 4, wherein the resin portion is made of one of a thermosetting resin, a thermoplastic resin and a silicone resin.

6. The semiconductor laser device according to claim 5, wherein the thermosetting resin is epoxy resin, the thermoplastic resin being one of polyphenylene sulfide, polyphthalamide and liquid crystalline polyester, the silicone resin being mixed with silica powder.

7. The semiconductor laser device according to claim 1, wherein the base and the block are provided with one of Ni/Pd/Au plating and Ni/Au plating.

8. The semiconductor laser device according to claim 1, wherein the semiconductor laser element is moisture-resistant.

9. A manufacturing method of a semiconductor laser device, the method comprising the steps of:
forming a stem including a base and a block fixed to the base;
fixing a lead in a through-hole formed in the base; and
mounting a semiconductor laser element on the block;
wherein in the step of forming the stem, the block and the base are formed integral with each other.

10. The manufacturing method of a semiconductor laser device according to claim 9, wherein the stem is formed by cold-forging of one of Cu and a Cu alloy.

11. The manufacturing method of a semiconductor laser device according to claim 9, wherein the lead is fixed to the through-hole by a resin material.

12. The manufacturing method of a semiconductor laser device according to claim 11, wherein the resin material is one of a thermosetting resin, a thermoplastic resin and a silicone resin.

13. The manufacturing method of a semiconductor laser device according to claim 12, wherein the thermosetting resin is epoxy resin, the thermoplastic resin being one of polyphenylene sulfide, polyphthalamide and liquid crystalline polyester, the silicone resin being mixed with silica powder.

14. The manufacturing method of a semiconductor laser device according to claim 9, further comprising an additional step for providing the stem with one of Ni/Pd/Au plating and Ni/Au plating, the additional step being performed after the stem forming step and before the lead fixing step.

15. The manufacturing method of a semiconductor laser device according to claim 9, further comprising an additional step for providing the lead with Au plating before the lead fixing step.
